(19) United States
(12) Patent Application Publication
(10) Pub. No.: US 2023/0238178 A1
(43) Pub. Date: Jul. 27, 2023

(54) Method for Controlling Turn-to-Turn Contact Resistance in REBCO Magnet Pancake Coils

(71) Applicant: The Florida State University Research Foundation, Inc., Tallahassee, FL (US)

(72) Inventors: Jun Lu, Tallahassee, FL (US); Iain R. Dixon, Tallahassee, FL (US); Mark D. Bird, Tallahassee, FL (US); Justin Deterding, Tallahassee, FL (US); Hongyu Bai, Tallahassee, FL (US); Emsley L. Marks, Tallahassee, FL (US); William Denis Markiewicz, Tallahassee, FL (US)

(21) Appl. No.: 18/157,146

(22) Filed: Jan. 20, 2023

Related U.S. Application Data
(60) Provisional application No. 63/267,023, filed on Jan. 21, 2022.

(51) Int. Cl. H01F 41/04; H01F 6/06

(52) U.S. Cl. CPC H01F 41/048; H01F 6/06

(57) ABSTRACT

Coils for superconducting magnets and methods of making coils for superconducting magnets and controlling the turn-to-turn contact resistance of coils. The coils include a REBCO superconducting tape coated with a layer of tin-lead solder, co-wound with an oxidized stainless steel tape. The inclusion of tin-lead solder on the REBCO tape and a layer of oxidation on the stainless steel tape advantageously allow for tuning of the turn-to-turn contact resistance of the coil, and advantageously mitigates the effect of repeated pressure cycling on the turn-to-turn contact resistance.

### CROSS-REFERENCE TO RELATED APPLICATION

This application claims priority to and the benefit of U.S. Provisional Patent Application No. 63/267,023, filed Jan. 21, 2022, which is incorporated by reference herein in its entirety.

### STATEMENT REGARDING FEDERALLY SPONSORED RESEARCH OR DEVELOPMENT

This invention was made with government support under grant number DMR-1644779 awarded by the National Science Foundation. The government has certain rights in the invention.

### FIELD OF THE DISCLOSURE

This disclosure relates generally to magnets and magnetic compositions and structures, and more particularly to Rare Earth-Barium-Copper Oxide (REBCO) magnets, and methods of making the same.

### BACKGROUND

No insulation (NI) REBCO pancake magnet coils, characterized by the elimination of typical turn-to-turn insulation, have several advantages over conventional insulated coils. For example, due to low turn-to-turn electrical resistance, when magnet quench happens in a NI REBCO coil, the quench current automatically bypasses the normal zone, and a hot spot is avoided. This self-quench-protection ability eliminates the need for a quench detection and protection system that can be very challenging and costly in a large high field REBCO magnet. Consequently, an NI REBCO coil is very stable, which allows for a thinner copper stabilizer on the REBCO conductor. With the thinner stabilizer and the elimination of turn-to-turn insulation, the NI REBCO provides a very high engineering current density and high mechanical strength. These suggest that this technology enables very compact magnets to reach a very high magnetic field.

There are, however, drawbacks in the current state of the NI REBCO coil technology. For example, high turn-to-turn contact resistance (R_{ct}) compromises the REBCO coil's self-quench-protection ability, risking magnet burn-out during a quench. On the other hand, low turn-to-turn contact resistance results in a REBCO coil magnet having a long charging and discharging delay with high energy losses during a field ramp. Low turn-to-turn contact resistance is further characterized by high transient electrical currents during magnet quench which results in high electromagnetic stressed that could damage the magnet.

Accordingly, improved coils for superconducting magnets and methods of controlling turn-to-turn contact resistance are needed.

### SUMMARY

In one aspect, improved methods for making superconducting magnets are provided. In one embodiment, a method includes providing a rare earth barium copper oxide (REBCO) superconducting tape; dipping the REBCO tape in a tin-lead solder bath to form a layer of tin-lead solder on a surface of the REBCO tape; oxidizing a stainless steel tape; and co-winding the dipped REBCO tape and the oxidized stainless steel tape into a coil.

In another aspect, improved coils for superconducting magnets are provided. In one embodiment, a coil for a superconducting magnet includes a REBCO superconducting tape; a layer of tin-lead solder coated on a surface of the REBCO superconducting tape; and a stainless steel tape, wherein the stainless steel tape has been oxidized, wherein the coated REBCO superconducting tape and oxidized stainless steel tape have been co-wound to form the coil.

### BRIEF DESCRIPTION OF THE DRAWINGS

The detailed description is set forth with reference to the accompanying drawings. The use of the same reference numerals may indicate similar to identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 is a cross-sectional view of a dipped REBCO coil in accordance with some embodiments of the present disclosure.

FIG. 2 is a schematic of a reel-to-reel solder dip coating process in accordance with some embodiments of the present disclosure.

FIG. 3 is a schematic of a reel-to-reel furnace in accordance with some embodiments of the present disclosure.

FIG. 4 is a perspective view of a magnet in accordance with some embodiments of the present disclosure.

FIG. 5 is a graph of turn-to-turn contact resistance versus pressure cycles for an as-received coil in accordance with some embodiments of the present disclosure.

FIG. 6 is a graph of turn-to-turn contact resistance versus temperature in accordance with some embodiments of the present disclosure.

FIG. 7 is a graph of turn-to-turn contact resistance versus temperature in accordance with some embodiments of the present disclosure.

FIG. 8 is a graph of turn-to-turn contact resistance versus pressure cycles in accordance with some embodiments of the present disclosure.

FIGS. 9A-9C are photographic images of cross-sections of a tape in accordance with some embodiments of the present disclosure.

### DETAILED DESCRIPTION

New and improved REBCO superconducting tapes and coils for superconducting magnets, and methods for their manufacture have been developed. In particular, the long magnet charging time, high field-ramp-losses, and high transient electrical currents during magnet quench characteristic of NI REBCO magnets having low contact resistance (R_{ct}) may be mitigated by controlling R_{ct}. Additionally, deteriorating self-quench-protection ability characteristic of NI REBCO magnets having high R_{ct} may be similarly mitigated by controlling R_{ct}. In various embodiments described herein, greater control over R_{ct} may be accomplished with a layer of tin-lead solder coated on a surface of a REBCO superconducting tape. A stainless steel tape may be used as mechanical reinforcement of the REBCO superconducting tape, which may be oxidized. In addition, without intending to be bound by any particular theory, it is believed that the coil with graded R_{ct} is used to reduce the ramp loss, as well as to improve stability and recovery speed after a quench in large NI REBCO magnets.

As used herein, “no insulation” or “NI” REBCO coils refer to REBCO coils that omit turn-to-turn insulation. “Turn-to-turn insulation,” in the context of high temperature superconductors, refers to an organic material such as polyimide film inserted between or co-wound with the layers of REBCO coil upon winding into a coil shape. Insulated RECBO coils are characterized by a radial resistance that is essentially infinite due to the inclusion of insulation. NI REBCO coils may have one or more resistive layers disposed on the REBCO superconducting coil, such as that described in U.S. Pat. No. 11,282,624 to Florida State University Research Foundation, Inc., which is incorporated herein by reference in pertinent part. Although these resistive layers interact with the R_{ct} of a REBCO superconducting coil, they do not insulate the REBCO superconducting coil, i.e., the radial resistance is not essentially infinite, so such layers are not necessarily excluded in NI REBCO coils.

In some embodiments, R_{ct} can be optimized to achieve a relatively short charging delay time and low ramp losses without jeopardizing the coil's self-quench-protection ability. Without intending to by any particular theory, it is believed that R_{ct} is a critical parameter in the development of NI coil technology.

As used herein, “substantially coated” is used to mean that all or a majority of at least one surface is coated with a substance, e.g., at least one side of a tape. For example, at least 50%, at least 60%, at least 70%, at least 80%, at least 90%, at least 95%, at least 99%, or any ranges therebetween, of the surface is coated with the substance.

As used herein, a “tape” is a long, thin, flexible strip of material, e.g., of a metal, as that term is understood in the art related to superconducting magnets.

FIG. 4 is a perspective view of a magnet 400 including a stack of a plurality of coils 402. The coils 402 may consist of the coated REBCO superconducting tape structures described herein. Other suitable configurations of the modified REBCO tapes and coils thereof may be used in other magnet structures or in other systems.

Throughout this disclosure, various aspects may be presented in a range format. It should be understood that the description in range format is merely for convenience and brevity and should not be construed as an inflexible limitation on the scope of the disclosure. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6, etc., as well as individual numbers within that range, for example, 1, 2, 3, 4, 5, and 6. This applies regardless of the breadth of the range.

As used herein, the term “about” with reference to dimensions refers to the dimension plus or minus 10%.

Methods of Making Coils for Superconducting Magnets

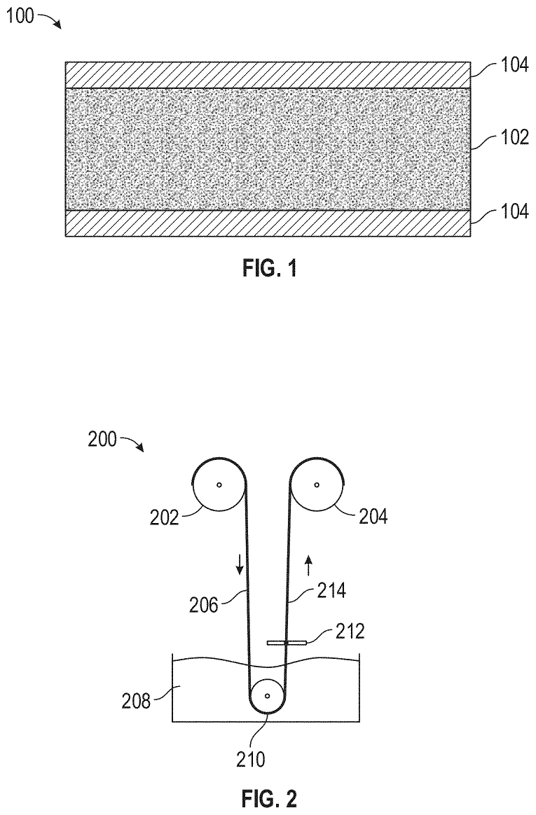

In some embodiments, a method of making a coil for a superconducting magnet includes providing a REBCO superconducting tape, and dipping the REBCO tape in a tin-lead solder bath to form a layer of tin-lead solder on a surface of the REBCO tape. In some embodiments, the method includes oxidizing a stainless steel tape, and co-winding the dipped REBCO tape and the oxidized stainless steel tape into a coil. In some embodiments, the coil for a superconducting magnet is a no-insulation coil. FIG. 1 shows, in a cross-sectional view, one embodiment of a dipped REBCO tape 100 including a REBCO tape 102 with layers of tin-lead solder 104.

In some embodiments, dipping the REBCO tape in a tin-lead solder bath includes a reel-to-reel dip coating. FIG. 2 shows a schematic of the reel-to-reel dip coating process 200 including a REBCO tape source reel 202 and coated REBCO tape collection reel 204. Uncoated REBCO tape 206 is fed from source reel 202 and passed into tin-solder bath 208. The REBCO tape passes around a stainless steel guide 210 before exiting the tin-solder bath 208, now coated in tin-solder. The REBCO tape passes through a silicone wipe 212 to wipe off excess tin-lead solder, producing the coated REBCO tape 214, which is collected on the collection reel 204.

In some embodiments, the REBCO tape passes through the tin-lead solder bath at a linear speed of from about 1 m/min to about 6 m/min. In some embodiments, the tin-lead solder bath is maintained at a temperature of from about 200° C. to about 260° C. In some embodiments, dipping the REBCO tape in the tin-lead solder bath is performed in a manner so as to minimize thermal degradation of the critical current (I_{c}) of the REBCO tape. In other words, the REBCO tape may pass though the tin-lead solder having a temperature and at a speed such that thermal degradation of I_{c} is negligibly small.

One skilled in the art in view of the description herein and the examples below can determine suitable tin-lead solder compositions and conditions to achieve the desired coating composition. In some embodiments, the tin-lead solder is 63/37 Sn—Pb. That is, the tin-lead solder is an alloy comprising 63% tin and 37% lead. In some embodiments, the layer of tin-lead solder has a thickness from about 1 μm to about 5 μm. For example, in various embodiments, the thickness of the layer of tin-lead solder is about 1 μm, about 2 μm, about 3 μm, about 4 μm, about 5 μm, or any ranges therebetween. As depicted in FIG. 1, both an upper surface of the REBCO tape and a lower surface of the REBCO tape may be coated with a layer of tin-lead solder. In some embodiments in which both an upper and lower surface of the REBCO tape is coated with a layer of tin-lead solder, each layer of tin-lead solder independently has a thickness of from about 1 μm to about 5 μm. In some embodiments, the mean thickness of the layer of tin-lead solder in a tape is between 1 μm and 5 μm.

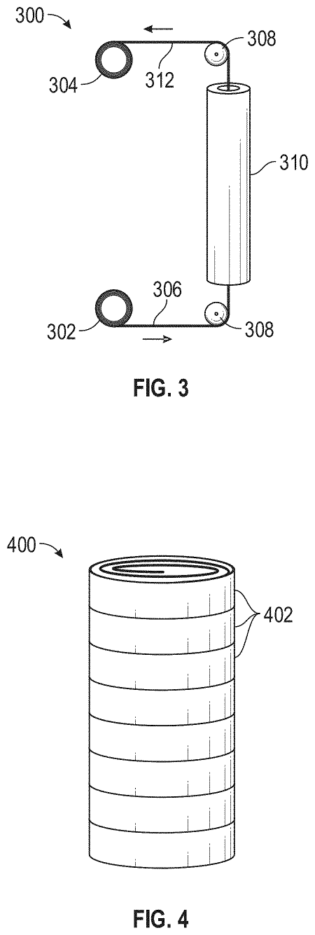

In some embodiments, oxidizing the stainless steel tape includes heating the stainless steel tape in a furnace, for example, by passing the stainless steel tape through the furnace on a reel-to-reel process. FIG. 3 shows a schematic of the furnace heating process 300 including a stainless steel tape source reel 302 and oxidized stainless steel tape collection reel 304. Clean stainless steel tape 306 is fed from source reel 302 and passed around stainless steel guide 308 and into furnace 310, which is open to the air. The stainless steel tape exits the furnace 310, now oxidized. The oxidized stainless steel tape 312 passes around stainless steel guide 308 and is collected on the collection reel 304.

One skilled in the art in view of the description herein and the examples below can determine suitable tin-lead solder compositions and conditions to achieve the desired degree of oxidation on the stainless steel tape, which depends at least in part on the composition of the clean (i.e., pre-oxidized) stainless steel tape, the temperature of the furnace, and the rate at which the stainless steel tape passes through the furnace. In some embodiments, the stainless steel tape includes 316L stainless steel. In some embodiments, heating the stainless steel tape includes passing the stainless steel tape through the furnace from reel-to-reel at a speed of about 1 m/min. In some embodiments, the furnace has a temperature of from about 400° C. to about 500° C. Without intending to be bound by any particular theory, it is believed that the temperature of the furnace through which the stainless steel tape passes affects the R_{ct} of the resulting coil after the oxidized stainless steel tape is co-wound with the tin-lead solder-coated REBCO tape. Increases in the furnace temperature result in increases in the R_{ct} of the coil. Thus, by controlling the temperature of the furnace during oxidation of the stainless steel tape, the R_{ct} of the resulting coil may be controlled.

In some embodiments, the method is effective to produce a coil having a turn-to-turn contact resistance (R_{ct}) of from about 1 mΩ-cm² to about 11 mΩ-cm². For example, the method may be effective to produce a coil having an R_{ct} of about 10 mΩ-cm² at 600° C. In some embodiments, the method is effective to produce a coil having an R_{ct} of about 4 mΩ-cm² at 500° C.

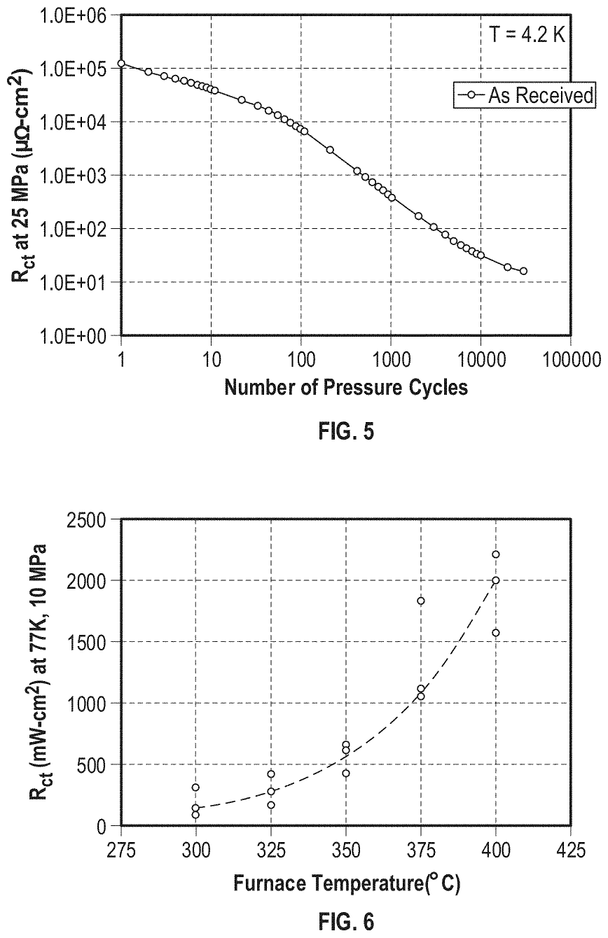

In some embodiments, the method is effective to produce a coil having an R_{ct} that reduces by less than 75% after 30,000 pressure cycles. It has been unexpectedly discovered that oxidation of the stainless steel tape prior to co-winding the oxidized stainless steel tape with the tin-lead solder-coated REBCO tape significantly mitigates deterioration in R_{ct} as a result of pressure cycling. FIG. 5 shows a graph of R_{ct} at 25 MPa versus the number of pressure cycles for a coil of co-wound REBCO tape and stainless steel tape as received (i.e., without tin-lead solder dipping or oxidation). The coil was subjected to pressure cycling from 2.5 MPa to 25 MPa and back, with the process repeated 30,000 times. As shown in FIG. 5 the R_{ct} of the coil dropped from just over an initial R_{ct} of 100 mΩ-cm² to around 20 μΩ-cm², a reduction of over 99%. As shown with respect to the Examples, coating the REBCO coil with a layer of tin-lead solder, and oxidizing the stainless steel tape prior to co-winding as described herein unexpectedly and advantageously suppressed this deterioration.

Coils for Superconducting Magnets

Coils for superconducting magnets are also disclosed herein. An example of a magnet 400 including coils 402 is shown in FIG. 4. The coils 402 may consist of the REBCO superconducting tape structures described herein. Other suitable configurations of the REBCO tapes and coils thereof may be used in other magnet structures or in other systems.

In some embodiments, the coil includes a REBCO superconducting tape with a layer of tin-lead solder coated on a surface of the REBCO superconducting tape. In some embodiments, the coil includes a stainless steel tape that has been oxidized. In some embodiments, the tin-lead solder-coated REBCO superconducting tape is co-wound with the oxidized stainless steel tape to form the coil. In some embodiments, the coil is a no-insulation (NI) coil that omits any turn-to-turn insulation.

In some embodiments, the layer of tin-lead solder includes 63/37 Sn—Pb having a thickness of from about 1 μm to about 5 μm. In some embodiments, the stainless steel tape includes 316L stainless steel.

In some embodiments, the coil has an R_{ct} of from about 1 mΩ-cm² to about 11 mΩ-cm². For example, the coil may have an R_{ct} of about 10 mΩ-cm² at 600° C. In some embodiments, the coil has an R_{ct} of about 4 mΩ-cm² at 500° C.

In some embodiments, the coil has a turn-to-turn contact resistance (R_{ct}) that reduces by less than 75% after 30,000 pressure cycles. It has been unexpectedly discovered that a stainless steel tape that has been oxidized co-wound with the tin-lead solder-coated REBCO tape significantly mitigates deterioration in R_{ct} as a result of pressure cycling. Absent oxidation on the stainless steel tape and the layer of tin-lead solder on the REBCO superconducting tape, a co-wound coil experiences a drop in R_{ct} of over 99% after 30,000 pressure cycles from 2.5 MPa to 25 MPa and back, as shown in FIG. 5. As shown with respect to the Examples, a coil formed from co-wound REBCO superconducting tape and stainless steel tape, with a layer of tin-lead solder on the REBCO superconducting coil and a layer of oxidation on the stainless steel tape, unexpectedly and advantageously suppressed this deterioration.

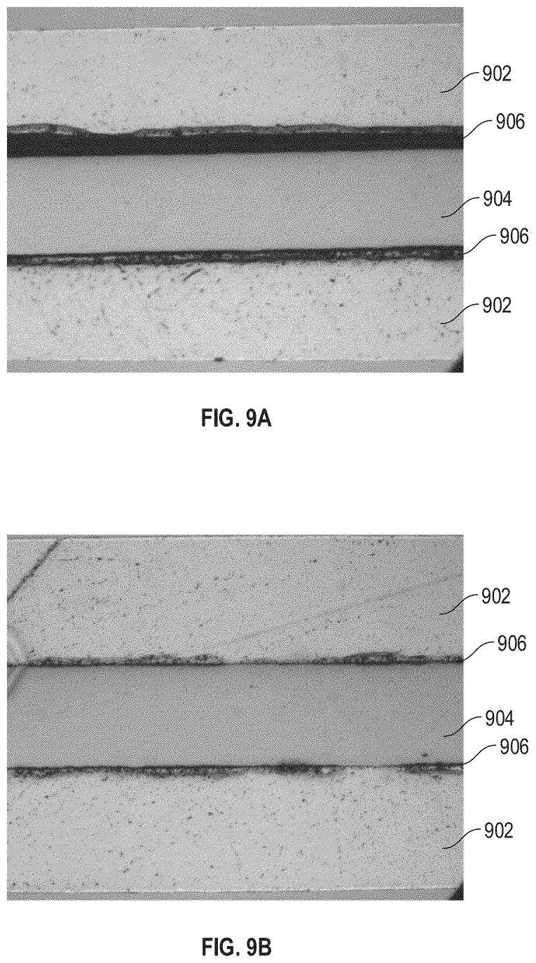

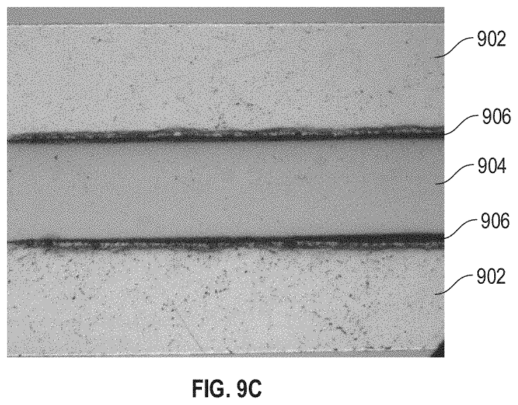

FIGS. 9A-9C depict cross-sections of a coil under 25 MPa pressure including REBCO superconducting tape 902, stainless steel tape 904, and a layer of tin-lead solder 906 coated on the surface of the REBCO superconducting tape 902. FIGS. 9A and 9C are taken at approximately at 1 mm from the outer edges of the tape, and FIG. 9B shows the center of the tape. Without intending to be bound by any particular theory, it is believed that the tin-lead solder “smoothens” the surface of the REBCO superconducting tape, i.e., fills in the gaps caused by microimperfections.

The invention may be further understood with reference to the following non-limiting examples.

### Example 1: Contact Resistance of Inventive Coils Using Horizontal Furnace

Coils were formed as described herein and the temperature of the furnace in which the stainless steel tape is oxidized was varied to measure the effect on the R_{ct} of the coil. In this test, the furnace was a horizontal furnace into which the stainless steel tape is inserted, allowed to rest for 1 minute during heat treatment, and then removed. Tests were run with furnace set points of 300° C., 325° C., 350° C., 375° C., and 400° C. The results are displayed in FIG. 6 where it can be seen that the R_{ct} of the coil (measured at 77K and 10 MPa) may be tuned to anywhere from about 150 μΩ-cm² to about 2000 μΩ-cm² by varying the temperature of the furnace.

### Example 2: Contact Resistance of Inventive Coils Using Vertical Furnace

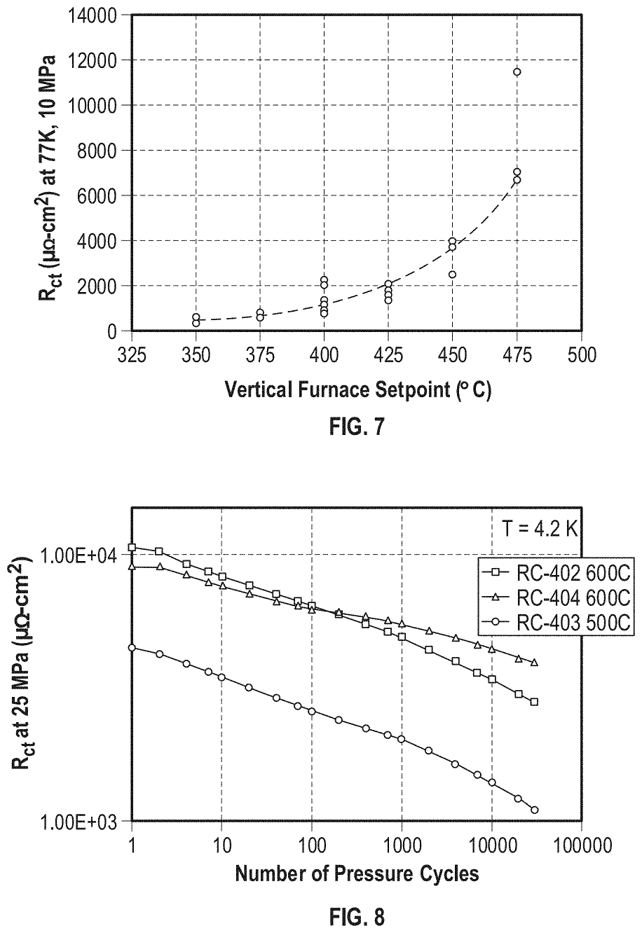

Coils were formed as described herein and the temperature of the furnace through which the stainless steel tape is passed was varied to measure the effect on the R_{ct} of the coil. In this test, the furnace was a vertical furnace through which the stainless steel tape was passed on a reel-to-reel system. Tests were run with furnace set points of 350° C., 375° C., 400° C., 425° C., 450° C., and 475° C. The results are displayed in FIG. 7, where it can be seen that the R_{ct} of the coil (measured at 77K and 10 MPa) may be tuned to anywhere from about 400 μΩ-cm² to about 7000 μΩ-cm² by varying the temperature of the furnace.

### Example 3: Effect of Pressure Cycling on Inventive Coils

Three coils were produced as described herein. Two coils were cycled between 2.5 MPa and 25 MPa at 600° C., and a third coil was cycled between 2.5 MPa and 25 MPa at 500° C. All three coils were cycled between 2.5 MPa and 25 MPa 30,000 times while measuring the turn-to-turn contact resistance (R_{ct}). The results of the test are presented in FIG. 8 and summarized below in Table A, along with a comparison with the as-received REBCO tape co-wound with the as-received stainless steel tape.

TABLE A
Summary of Pressure Cycling Test

| | Initial R_{ct} | R_{ct} after 30k | % change in R_{ct} |
|---|---|---|---|
| Sample | (mΩ-cm²) | cycles (mΩ-cm²) | after 30k cycles |
| As-received | 12.1 | 0.0015 | 99.99% |
| Rc-402 | 10.5 | 2.8 | 73.33% |
| 600 C., tinned | | | |
| Rc-404 | 9.0 | 3.9 | 56.67% |
| 600 C., tinned | | | |
| Rc-403 | 4.4 | 1.1 | 75.00% |
| 500 C., tinned | | | |

As shown in Table A and FIGS. 5 and 8, dipping the REBCO superconducting tape in tin-lead solder and oxidizing the stainless steel tape before co-winding into a coil has the unexpected benefit of significantly reducing the effect of pressure cycling on the coil compared to an as-received REBCO superconducting tape co-wound with an as-received stainless steel tape.

While the disclosure has been described with reference to a number of embodiments, it will be understood by those skilled in the art that the disclosure is not limited to such embodiments. Rather, the disclosure can be modified to incorporate any number of variations, alterations, substitutions, or equivalent arrangements not described herein, but which are commensurate with the spirt and scope of the disclosure. Conditional language used herein, such as “can,” “could,” “might,” or “may,” unless specifically stated otherwise, or otherwise understood within the context as used, generally is intended to convey that certain embodiments include, while other embodiments do not include, certain features, elements or functional capabilities. Additionally, while various embodiments of the disclosure have been described, it is to be understood that aspects of the disclosure may include only some of the described embodiments. Accordingly, the disclosure it not to be seen as limited by the foregoing described, but is only limited by the scope of the appended claims.

That which is claimed is:

1. A method of making a coil for a superconducting magnet, the method comprising:
providing rare earth barium copper oxide (REBCO) superconducting tape;
dipping the REBCO tape in a tin-lead solder bath to form a layer of tin-lead solder on a surface of the REBCO tape;
oxidizing a stainless steel tape; and
co-winding the dipped REBCO tape and the oxidized stainless steel tape into a coil.

2. The method of claim 1, wherein the coil is a no-insulation coil.

3. The method of claim 1, wherein dipping the REBCO tape in the tin-lead solder bath comprises a reel-to-reel dip coating at a speed of between about 1 m/min to about 6 m/min.

4. The method of claim 3, wherein a thermal degradation of the REBCO tape during the dipping is negligible.

5. The method of claim 3, wherein the reel-to-reel dip coating comprises a silicone wipe after the REBCO tape exits the tin-lead solder bath for removing excess liquid solder.

6. The method of claim 1, wherein the tin-lead solder comprises 63/37 Sn—Pb.

7. The method of claim 1, wherein the layer of tin-lead solder has a thickness of from about 1 μm to about 5 μm.

8. The method of claim 1, wherein the tin-lead solder bath has a temperature of between about 200° C. to 260° C.

9. The method of claim 1, wherein the stainless steel tape comprises 316L stainless steel.

10. The method of claim 1, wherein oxidizing the stainless steel tape comprises heating the stainless steel tape in a furnace.

11. The method of claim 10, wherein heating the stainless steel tape comprises passing the stainless steel tape through the furnace from reel-to-reel at a speed of about 1 m/min.

12. The method of claim 10, wherein the furnace has a temperature of about 400° C. to about 500° C.

13. The method of claim 1, wherein the coil has a turn-to-turn contact resistance (R_{ct}) of from about 1 mΩ-cm² to about 11 mΩ-cm².

14. The method of claim 1, wherein the coil has a turn-to-turn contact resistance (R_{ct}) of about 10 mΩ-cm² at 600° C.

15. The method of claim 1, wherein the coil has a turn-to-turn contact resistance (R_{ct}) of about 4 mΩ-cm² at 500° C.

16. The method of claim 1, wherein the coil has a turn-to-turn contact resistance (R_{ct}) that reduces by less than 75% after 30,000 pressure cycles.

17. The method of claim 1, wherein, when the coil has been cycled between pressures of 2.5 MPa to 25 MPa 30,000 times, the turn-to-turn contact resistance (R_{ct}) reduces by less than 75%.

18. A no-insulation coil for a superconducting magnet comprising:
a rare earth barium copper oxide (REBCO) superconducting tape;
a layer of tin-lead solder coated on a surface of the REBCO superconducting tape; and
a stainless steel tape, wherein the stainless steel tape has been oxidized,
wherein the coated REBCO superconducting tape and oxidized stainless steel tape have been co-wound to form the coil.

19. The coil of claim 18, wherein:
the tin-lead solder is 63/37 Sn—Pb;
the stainless steel tape comprises 316L stainless steel; and/or
the layer of tin-lead solder has a thickness of from about 1 μm to about 5 μm.

20. The coil of claim 18, wherein:
the coil has a turn-to-turn contact resistance (R_{ct}) of from about 1 mΩ-cm² to about 11 mΩ-cm²;
the coil has a turn-to-turn contact resistance (R_{ct}) of about 10 mΩ-cm² at 600° C.;
the coil has a turn-to-turn contact resistance (R_{ct}) of about 4 mΩ-cm² at 500° C.;
the coil has a turn-to-turn contact resistance (R_{ct}) that reduces by less than 75% after 30,000 pressure cycles; and/or.
when the coil has been cycled between pressures of 2.5 MPa to 25 MPa 30,000 times, the turn-to-turn contact resistance (R_{ct}) reduces by less than 75%.
